(19) United States
(12) Patent Application Publication
(10) Pub. No.: US 2010/0163092 A1
(43) Pub. Date: Jul. 1, 2010

(54) PHOTOVOLTAIC DEVICE

(76) Inventor: Nobuyoshi Takeuchi, Tochigi (JP)

Correspondence Address: ARENT FOX LLP, 1050 CONNECTICUT AVENUE, N.W., SUITE 400, WASHINGTON, DC, 20036, US

(21) Appl. No.: 11/997,871

(22) PCT Filed: Jul. 4, 2006
(86) PCT No.: PCT/JP2006/313258

§ 371 Date: Mar. 1, 2010

(30) Foreign Application Priority Data
Aug. 2, 2005 (JP) 2005-223728

(51) Int. Cl. H01L 31/042

(52) U.S. Cl. 136/244

(57) ABSTRACT

A terminal box 3 is provided on the reverse side of each module in a plurality of solar cell modules 2 which forms a solar cell module group 1. A positive connecting terminal 4 and a negative connecting terminal 5 are attached to the side surface of the terminal box 3. Two cables 6, 7 come out of the terminal box 3. A positive connecting terminal 8 is attached to one cable 6 and a negative connecting terminal 9 is attached to the other cable 7. The positive connecting terminal 8 of the solar cell module 2 is connected to the positive connecting terminal 4 of the adjacent solar cell module 2, while the negative connecting terminal 9 is attached to the negative connecting terminal 5 of the adjacent solar cell module 2. The positive connecting terminal 8 of the last solar cell module 2 is connected to the positive connecting terminal 4 of the first solar cell module 2, while the negative connecting terminal 9 of the last solar cell module 2 is connected to the negative connecting terminal 5 of the first solar cell module 2, thereby completing the solar cell module group 1 which is connected in parallel in a closed loop.

### BACKGROUND OF THE INVENTION

1. Field of the Invention

The present invention relates to a photovoltaic device in which two or more thin film type solar cell modules are connected in parallel.

2. Description of the Prior Art

FIG. 1 shows a schematic view of a general photovoltaic device. The photovoltaic device mainly consists of a solar cell module and a power conditioner. Power obtained by a solar cell is input into the power conditioner, is converted into the same form (for example, 100V) as a commercial power source, and is supplied to households, factories and the like. In order to input power into the power conditioner for conversion, it is desirable that the voltage be increased to make the conversion loss low.

The solar cell module is formed by connecting a plurality of cells, each of which is a minimum unit for receiving light and converting it to electric energy. The cell is classified into a bulk type and a thin film type depending upon the thickness of a semiconductor.

The bulk type solar cell is, for example, a single crystal silicon solar cell which can be obtained by slicing a silicon wafer from a silicon ingot. Since one cell can only produce a low voltage of about 0.6V, many cells have to be connected in series for use in a household power source and as a result, the degrees of freedom in the design become low. Further, since many small cells are disposed, they are neither attractive to the eye nor suitable for a building component. Still further, since the number of cells which can be disposed on one module is limited due to area restrictions, one module made of the bulk type solar cell can only produce a comparatively low voltage of 40-60V.

Referring to the thin film type solar cell, a semiconductor layer (i.e., a light absorption layer) has a thickness of several tens of μm to several μm or less. The cell is classified into an Si thin film type and a compound thin film type. The compound thin film type can also be classified into an II-VI group compound type and a chalcopyrite type. FIG. 2 shows a structure of the thin film type solar cell. Formed on a substrate are a lower electrode, a light absorption layer, a buffer layer and an upper electrode layer. A number of serial steps is formed by scribing them in the thickness direction. A given voltage can be designed by changing the number of serial steps.

For example, since a voltage of 50-100V can be obtained by one cell, it is also easy to make one module as shown in FIG. 1 with one cell or two to three cells to secure a voltage of 100-300V. In the case of the thin film type solar cell, since the outer appearance is of one plate in black or blue, it can also be used as a panel for a wall or roof material without imparting an odd appearance and excels even as a material for building construction.

A proposal for forming a photovoltaic device with such a thin film type solar cell is disclosed in Patent Document 1.

In this Patent Document 1; as shown in FIG. 3, two positive connecting terminals and two negative connecting terminals are provided on the reverse side of each solar cell. The positive connecting terminal of one solar cell is connected to the positive connecting terminal of the adjacent solar cell, while the negative connecting terminal is connected to the negative connection terminal of the adjacent solar cell to form a module of adjacent solar cells connected in parallel in a string shape. One end of the module is connected to a power conditioner and the other end is terminated by an insulation cap.

Patent Document 1 Japanese Patent Application Publication No. 2002-289893

In the module which is formed of solar cells connected in parallel in a string shape, since the voltage does not change unlike in a series connection even though the circuit becomes disconnected, it is difficult to discover the disconnection. As a result, the cells from the disconnection location to the end generate electricity, but it is not possible to obtain electric power from the cell and thus, the electricity is wasted.

In the case where the module is connected in parallel in a string shape, the power supply wiring channel becomes long and power loss due to electric resistance in the wiring becomes large.

Further, as a terminating process, it is necessary to mount an insulation cap on the connecting terminal. Operation is therefore troublesome and water may infiltrate into the terminated area by a factor such as a secular change.

### SUMMARY OF THE INVENTION

It is therefore an object of the present invention to solve the problems as seen in the prior art and to provide a photovoltaic device which can surely supply power even though a cable connecting modules or the circuit is disconnected.

In order to attain this object, a photovoltaic device according to the present invention is provided, which comprises a plurality of solar cell modules, a solar cell module group, and a connection box, wherein each solar cell module has two positive connecting terminals and two negative connecting terminals, the solar cell module group is formed in a closed loop by connecting each positive connecting terminal of the solar cell modules in parallel and by connecting each negative connecting terminal of the solar cell modules in parallel, and the connection box is provided on a part of the solar cell module group formed in a closed loop to supply a power conditioner with power generated in that solar cell module group.

The connection box has, for example, two positive connecting terminals and two negative connecting terminals. One of the positive connection terminals is connected to a positive connecting terminal of the one adjacent solar cell module and the other of the positive connecting terminals is connected to a positive connecting terminal of the other adjacent solar cell module, while one of the negative connecting terminals is connected to a negative connecting terminal of the one adjacent solar cell module and the other of the negative connecting terminals is connected to a negative connecting terminal of the other adjacent solar cell module. Two positive connecting terminals and two negative connecting terminals of the connecting box converge to be connected to the power conditioner.

### BRIEF DESCRIPTION OF THE DRAWINGS

The above and other objects, features and advantages of the present invention will become more apparent from the following description when taken in conjunction with the accompanying drawings.

FIG. 1 is a schematic view of a general photovoltaic device;

FIG. 2 is a cross-sectional view of a thin film type solar cell;

FIG. 3 is an explanatory view of a conventional photovoltaic device using the thin film type solar cell;

FIG. 4 is a view showing an entire structure of a photovoltaic device according to the present invention;

FIG. 5 is a back view of a solar cell module; and

FIG. 6 is a view showing one example of a circuit within a connection box.

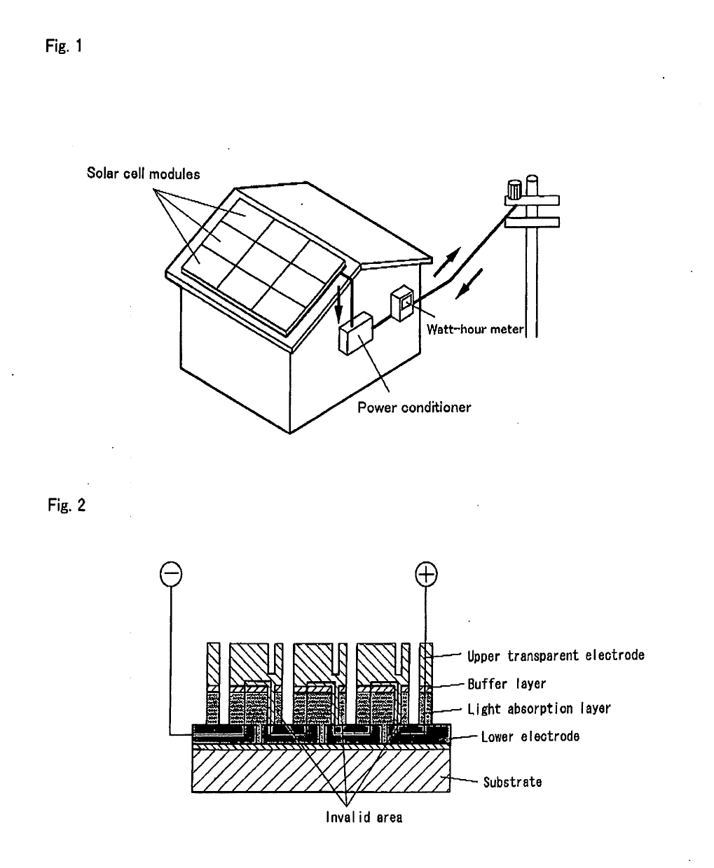

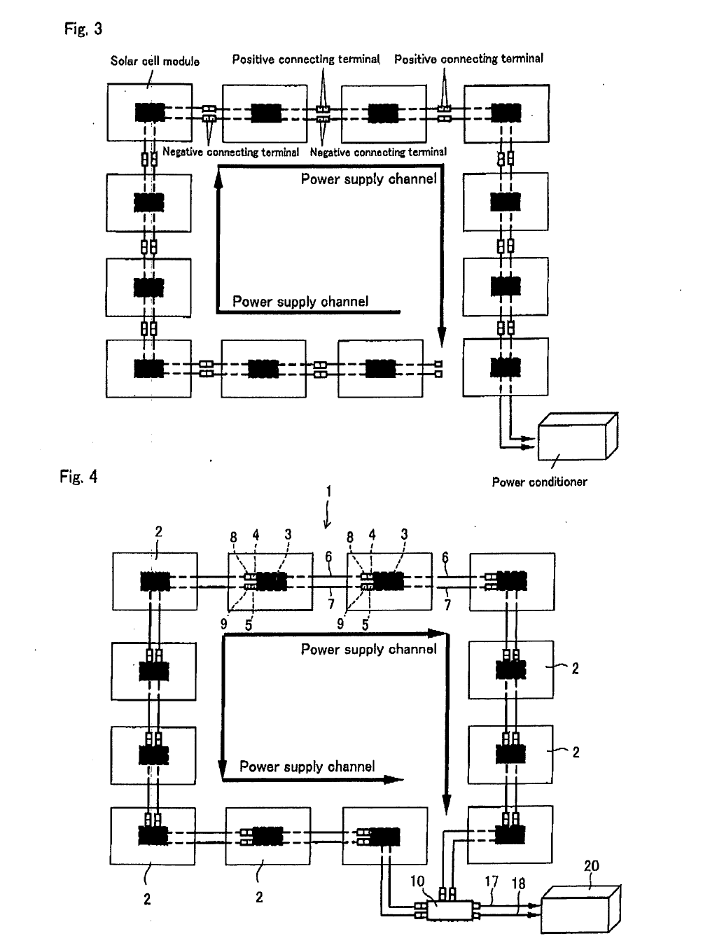

### DETAILED DESCRIPTION OF THE PREFERRED EMBODIMENTS

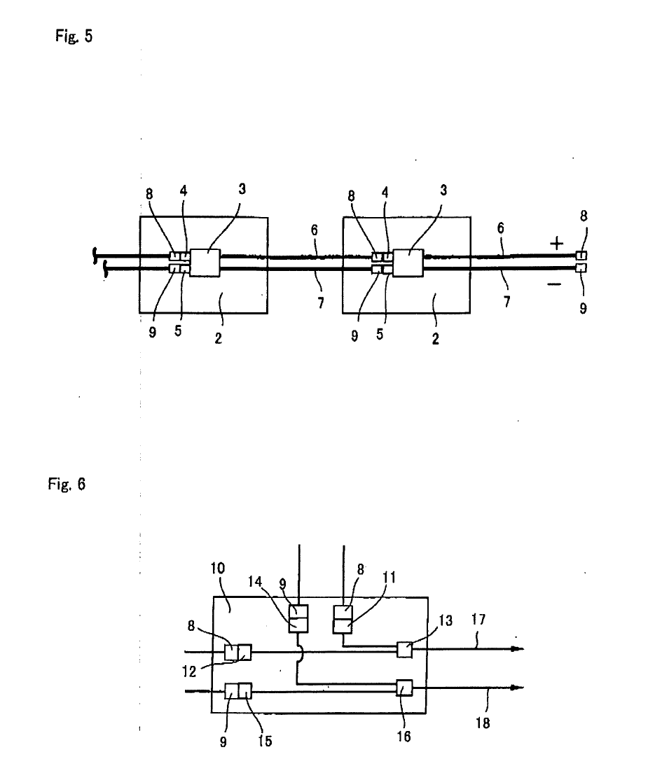

A preferred embodiment of the present invention will now be described with reference to the accompanying drawings. FIG. 4 is a view showing an entire structure of a photovoltaic device according to the present invention. FIG. 5 is a back view of a solar cell module and FIG. 6 is a view showing one example of a circuit within a connection box.

A photovoltaic device mainly consists of a solar cell module group 1 and a power conditioner 20. The solar cell module group 1 is formed in a closed loop shape by connecting two or more solar cell modules 2 in parallel.

More specifically, as shown in FIG. 5, a terminal box 3 is provided on the reverse side of the solar cell module 2. A positive connecting terminal 4 and a negative connecting terminal 5 are attached to the side surface of the terminal box 3. Two cables come out of the terminal box 3. A positive connecting terminal 8 is attached to one cable 6, while a negative connecting terminal 9 is attached to another cable 7.

In the shown example, the cables are arranged to come out only in one side direction from the terminal box 3, but it is also possible to allow two cables to come out in another side direction, wherein the positive connecting terminal 4 and the negative connecting terminal 5 can be attached to the cables, respectively.

The solar cell module 2 is composed of a thin film type cell which is provided with a plurality of serial steps. For example, a ceramic interlayer is provided on one surface side of a flexible substrate made of or including mica for planarization. A lower electrode is formed on the planarized surface and a light absorption layer of a chalcopyrite type is formed on the surface side of the lower electrode. An upper electrode is formed on the light absorption layer through a buffer layer. It is also considered that a layer made of ceramics is formed on the reverse side of the mica substrate to prevent a warp.

The positive connecting terminal 8 of the solar cell module 2 is connected to the positive connecting terminal 4 of the adjacent solar cell module 2, while the negative connecting terminal 9 is connected to the negative connecting terminal 5 of the adjacent solar cell module 2. The positive connecting terminal 8 of the last solar cell module 2 is connected to the positive connecting terminal 4 of the first solar cell module 2, while the negative connecting terminal 9 of the last solar cell module 2 is connected to the negative connecting terminal 5 of the first solar cell module 2, thereby completing the solar cell module group 1 which is connected in parallel in the closed loop shape.

In the present invention, a connection box 10 for supplying the power conditioner 20 with power is provided on a part of the solar cell module group 1 which is connected in parallel in a closed loop shape.

The connection box 10 is provided, as shown in FIG. 6, with three positive connecting terminals 11, 12, 13 and three negative connecting terminals 14, 15, 16. Connected to the positive connecting terminal 11 is the positive connecting terminal of the horizontally adjacent one solar cell module 2, while connected to the positive connecting terminal 12 is the positive connecting terminal of the horizontally adjacent other solar cell module 2, and these converge at the positive connecting terminal 13. Connected to the negative connecting terminal 14 is the negative connecting terminal of the horizontally adjacent one solar cell module 2, while connected to the negative connecting terminal 15 is the negative connecting terminal of the horizontally adjacent other solar cell module 2, and these converge at the negative connecting terminal 16.

Cables 17, 18 are adapted to come out of the positive connecting terminal 13 and the negative connecting terminal 16 of the connection box 10, respectively, and these cables 17, 18 are connected to the power conditioner 20.

In this manner, power generated in each solar cell module 2 enters the connection box 10 through the right and left power supply channel and is fed to the power conditioner 20 through the connection box 10, which is then converted to commercial power to be supplied to each household. Even though part of the closed loop is disconnected, power is designed to enter the connection box 10 through the right and left power supply channel and therefore, power is not wasted.

It is to be understood that the present invention is not limited to the shown examples. For example, the connection box is not limited to one, but two connection boxes can be provided at the target locations of the closed loop. Further, two or more solar cell module groups 1 can also be gathered to be connected in series or in parallel.

### EFFECTS OF THE INVENTION

According to the present invention, a solar cell module is composed of a thin film type solar cell and is provided with two positive connecting terminals and two negative connecting terminals. A solar cell module group of a closed loop is formed by connecting each positive connecting terminal of a plurality of solar cell modules in parallel and by connecting each negative connecting terminal thereof in parallel, A connection box is provided on a part of the solar cell module group of the closed loop to be connected to a power conditioner. A positive connecting terminal of the connection box is connected to a positive connecting terminal of the adjacent solar cell module, while a negative connecting terminal of the connection box is connected to a negative connecting terminal of the adjacent solar cell module. In this manner, even though part of the closed loop is disconnected, power can be fed with remaining nearly unaffected.

Further, according to the present invention, a power supply wiring channel becomes shorter than that in a string shape because power is fed to the connection box from the right and loft routes and as a result, power loss due to electric resistance can be reduced.

In the following table, power loss is compared between the string shaped power supply wiring channel and the closed loop power supply wiring channel according to the present invention. The number of connections of the solar cell modules is 16 in each case. However, in the case of the closed loop, the number of connections was set at 8 and the power loss for 8 was doubled because power is fed from the right and left routes. Referring to calculation of power loss, each wiring resistance is set at R (0.2Ω) and power supply from each solar cell module is set at i (0.6 W). The voltage of a system remains unchanged because of parallel connection. However, assuming that, an electric current from each solar cell module flows into the downstream of the system and the current according to the number of connections is added together, power loss was calculated from i2R (Ohm's law).

TABLE 1

| | |
|---|---|
| Connection | |
| without loop | Connection with loop |

| Number of | | Number of | |
|---|---|---|---|
| connections | Power loss | connections | Power loss |
| 1 | 0.072 | 1 | 0.072 |
| 2 | 0.288 | 2 | 0.288 |
| 3 | 0.648 | 3 | 0.648 |
| 4 | 1.152 | 4 | 1.152 |
| 5 | 1.8 | 5 | 1.8 |
| 6 | 2.592 | 6 | 2.592 |
| 7 | 3.528 | 7 | 3.528 |
| 8 | 4.608 | 8 | 4.608 |
| 9 | 5.832 | | 14.688 |
| 10 | 7.2 | | |
| 11 | 8.712 | | |
| 12 | 10.368 | | |
| 13 | 12.168 | | |
| 14 | 14.112 | | |
| 15 | 16.2 | | |
| 16 | 18.432 | | |
| | 107.712 | | |

As is obvious from the table, power loss in the case of the conventional string shaped parallel connection was 107.712 W. On the contrary, power loss in the case of the closed loop parallel connection according to the present invention was 29376 W (14.688×2) and as a result, power loss of 73% could be cut down.

According to the present invention, it is not necessary to terminate a cable (i.e., connecting terminal) because the solar cell module of the last end does not exist. In this manner, workability improves.

Further, by removing the connecting terminals (i.e., connector) of the connection box and each module, it is possible to readily conduct a cable check of a circuit.

What is claimed is:

1. A photovoltaic device comprising:
a plurality of solar cell modules;
a solar cell module group; and
a connection box;
wherein:
each solar cell module has two positive connecting terminals and two negative connecting terminals;
the solar module group is formed in a closed loop by connecting each positive connecting terminal of the solar cell modules in parallel and by connecting each negative connecting terminal of the solar cell modules in parallel; and
the connection box is provided on a part of the solar cell module group formed in a closed' loop to supply a power conditioner with power generated in that solar cell module group.
